(19) United States
(12) Patent Application Publication
(10) Pub. No.: US 2026/0358377 A1
(43) Pub. Date: Nov. 12, 2026

(54) DISCHARGE DEVICE AND TESTING MACHINE

(71) Applicant: Test Research, Inc., Taipei City (TW)

(72) Inventors: Ming-Hsien LIU, Taipei City (TW); Po-Zhong CHEN, Taipei City (TW)

(21) Appl. No.: 19/276,033

(22) Filed: Jul. 22, 2025

(30) Foreign Application Priority Data
May 7, 2025 (TW) 114117197

(51) Int. Cl. G01R 1/20

(52) U.S. Cl. CPC G01R 1/203

(57) ABSTRACT

The present disclosure provides a discharge device. The discharge device includes a floating active load and a resistor network. In structure, the resistor network is electrically connected to the floating active load. Moreover, the present disclosure also provides a testing machine, in which the testing machine includes the discharge device.

### CROSS-REFERENCE TO RELATED APPLICATION

This application claims priority to Taiwan Application Serial Number 114117197, filed May 7, 2025, which is herein incorporated by reference.

### BACKGROUND

### Field of Invention

The present invention relates to hardware devices, and more particularly, discharge devices and testing machines.

### Description of Related Art

The time period of the discharge of the traditional testing machine is long. To speed up the discharge speed, larger resistor volume and heat dissipation areas are required. The discharge voltage range of the traditional testing machine is narrow (e.g., less than 35V). To increase the discharge voltage range, the larger resistor volume and the heat dissipation area are required.

In view of the foregoing, there still exist some problems on above discharge technology that awaits further improvement. However, those skilled in the art sought vainly for a solution. Accordingly, there is an urgent need in the related field to effectively improve the discharge speed and increase the discharge voltage range.

### SUMMARY

The following presents a simplified summary of the disclosure in order to provide a basic understanding to the reader. This summary is not an extensive overview of the disclosure and it does not identify key/critical components of the present invention or delineate the scope of the present invention. Its sole purpose is to present some concepts disclosed herein in a simplified form as a prelude to the more detailed description that is presented later.

According to embodiments of the present disclosure, the present disclosure provides discharge devices and testing machines, to solve or circumvent aforesaid problems and disadvantages in the related art.

An embodiment of the present disclosure is related to a discharge device that includes a floating active load and a resistor network. The resistor network is electrically connected to the floating active load.

In one embodiment of the present disclosure, the floating active load includes a bridge rectifier circuit and an active load. The bridge rectifier circuit is electrically connected to the resistor network. The active load is electrically connected to the bridge rectifier circuit.

In one embodiment of the present disclosure, the bridge rectifier circuit includes a first diode, a second diode, a third diode and a fourth diode. A cathode of the first diode is electrically connected to an end of the active load. A cathode of the second diode is electrically connected to the end of the active load, and an anode of the second diode is electrically connected to the resistor network. A cathode of the third diode is electrically connected to an anode of the first diode, and an anode of the third diode is electrically connected to another end of the active load. A cathode of the fourth diode is electrically connected to the anode of the second diode, and an anode of the fourth diode is electrically connected to the another end of the active load.

In one embodiment of the present disclosure, the active load includes a current source and a resistance element. An end of the current source is electrically connected to the cathode of the first diode and the cathode of the second diode. An end of the resistance element is electrically connected to another end of the current source, and another end of the resistance element is electrically connected to the anode of the third diode and the anode of the fourth diode.

In one embodiment of the present disclosure, the discharge device further includes a first switching circuit. An end of the first switching circuit is electrically connected to an end of the floating active load, another end of the first switching circuit is electrically connected to an end of the resistor network, and another end of the resistor network is electrically connected to another end of the floating active load.

In one embodiment of the present disclosure, the resistor network includes a plurality of resistors, the first switching circuit includes a plurality of switches, the plurality of switches are electrically connected to the plurality of resistors respectively, the plurality of resistors are connected in parallel with each other, and an on/off state of the plurality of switches of the first switching circuit determines a parallel resistance value of the resistor network.

In one embodiment of the present disclosure, the discharge device further includes a second switching circuit, a third switching circuit and a voltage measurement circuit. The second switching circuit is electrically connected to the end of the first switching circuit and a DUT (device under test) connection end, and the third switching circuit electrically connected to above-mentioned another end of the resistor network and another DUT connection end. Two ends of the voltage measurement circuit are electrically connected to the second switching circuit and the third switching circuit respectively, and the on/off state of the plurality of the switches of the first switching circuit is based on an voltage value between the DUT connection end and the another DUT connection end, and the voltage value is measured by the voltage measurement circuit.

Another embodiment of the present disclosure is related to a testing machine that includes a measurement unit, a discharge unit and a control unit. The measurement unit is configured to measure a voltage value of a DUT. The discharge unit is electrically connected to the DUT. The control unit is electrically connected to the measurement unit and the discharge unit, the discharge unit includes a floating active load and a resistor network, and the resistor network is electrically connected to the floating active load.

In one embodiment of the present disclosure, the resistor network includes a plurality of resistors, the control unit is electrically connected to the plurality of the resistors through a plurality of switches, and the control unit controls an on/off state of the plurality of the switches based on the voltage value of the DUT, thereby adjusting a parallel resistance value of the resistor network.

In one embodiment of the present disclosure, the floating active load includes a bridge rectifier circuit and an active load. The bridge rectifier circuit is electrically connected to the resistor network. The active load electrically connected to the bridge rectifier circuit.

In one embodiment of the present disclosure, the bridge rectifier circuit includes a first diode, a second diode, a third diode and a fourth diode. A cathode of the first diode is electrically connected to an end of the active load. A cathode of the second diode is electrically connected to the end of the active load, and an anode of the second diode is electrically connected to the resistor network. A cathode of the third diode is electrically connected to an anode of the first diode, and an anode of the third diode is electrically connected to another end of the active load. A cathode of the fourth diode is electrically connected to the anode of the second diode, and an anode of the fourth diode is electrically connected to above-mentioned another end of the active load.

In one embodiment of the present disclosure, the active load includes a current source and a resistance element. An end of the current source is electrically connected to the cathode of the first diode and the cathode of the second diode. An end of the resistance element is electrically connected to another end of the current source, and another end of the resistance element is electrically connected to the anode of the third diode and the anode of the fourth diode.

In one embodiment of the present disclosure, the control unit includes a first switching circuit. An end of the first switching circuit is electrically connected to an end of the floating active load, another end of the first switching circuit is electrically connected to an end of the resistor network, and another end of the resistor network is electrically connected to another end of the floating active load.

In one embodiment of the present disclosure, the resistor network includes a plurality of resistors, the first switching circuit includes a plurality of switches, the plurality of switches are electrically connected to the plurality of resistors respectively, the plurality of resistors are connected in parallel with each other, and an on/off state of the plurality of switches of the first switching circuit determines a parallel resistance value of the resistor network.

In one embodiment of the present disclosure, the control unit further includes a second switching circuit and a third switching circuit. The second switching circuit is electrically connected to the end of the first switching circuit and a DUT connection end; and the third switching circuit electrically connected to above-mentioned another end of the resistor network and another DUT connection end. The measurement unit includes a voltage measurement circuit, wherein two ends of the voltage measurement circuit are electrically connected to the second switching circuit and the third switching circuit respectively, and the on/off state of the plurality of the switches of the first switching circuit is based on the voltage value between the DUT connection end and the another DUT connection end, and the voltage value is measured by the voltage measurement circuit.

In view of the above, technical advantages are generally achieved, by embodiments of the present disclosure. With the discharge device and the testing machine of the present disclosure, there is no influence of the voltage polarity during the discharge, the discharge voltage range is increased, and the time period of the discharge is shortened.

Many of the attendant features will be more readily appreciated, as the same becomes better understood by reference to the following detailed description considered in connection with the accompanying drawings.

### BRIEF DESCRIPTION OF THE DRAWINGS

The invention can be more fully understood by reading the following detailed description of the embodiment, with reference made to the accompanying drawings as follows:

FIG. 1 is a block diagram of a testing machine according to some embodiments of the present disclosure; and

FIG. 2 is a circuit diagram of a discharge device according to some embodiments of the present disclosure.

### DETAILED DESCRIPTION

Reference will now be made in detail to the present embodiments of the invention, examples of which are illustrated in the accompanying drawings. Wherever possible, the same reference numbers are used in the drawings and the description to refer to the same or like parts.

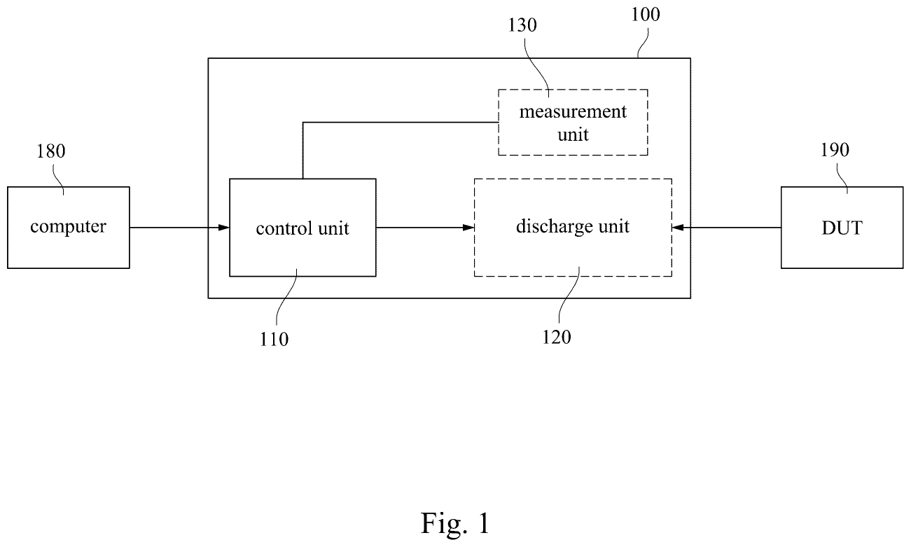

Referring to FIG. 1, in one aspect, the present disclosure is directed to a discharge unit 120. This discharge unit 120 may be easily integrated into a testing machine 100 and may be applicable or readily adaptable to all technologies. Accordingly, the discharge unit 120 of the testing machine 100 has advantages. Herewith the testing machine 100 is described below with FIG. 1.

The subject disclosure provides the testing machine 100 in accordance with the subject technology. Various aspects of the present technology are described with reference to the drawings. In the following description, for purposes of explanation, numerous specific details are set forth in order to provide a thorough understanding of one or more aspects. It can be evident, however, that the present technology can be practiced without these specific details. In other instances, well-known structures and devices are shown in block diagram form in order to facilitate describing these aspects. The word “exemplary” is used herein to mean “serving as an example, instance, or illustration.” Any embodiment described herein as “exemplary” is not necessarily to be construed as preferred or advantageous over other embodiments.

FIG. 1 is a block diagram of the testing machine 100 according to some embodiments of the present disclosure. As shown in FIG. 1, a computer 180 can be electrically connected to the testing machine 100, and the testing machine 100 can be electrically connected to a DUT (device under test) 190. It should be noted that when an element is referred to as being “connected” or “coupled” to another element, it can be directly connected or coupled to the other element or intervening elements may be present. In contrast, when an element is referred to as being “directly connected” or “directly coupled” to another element, there are no intervening elements present. For example, the computer 180 can be directly electrically connected to the testing machine 100, or the computer 180 can be indirectly electrically coupled with the testing machine 100 through external circuits.

In practice, for example, the computer 180 can be a personal computer, a server, or computer hardware, and the DUT 190 can be a circuit board, a capacitor, a chip, a wafer, a display panel, or another electronic product to be tested. The testing machine 100 may be a detection device, a test device or other machine.

In some embodiments of the present disclosure, the testing machine 100 includes a measurement unit 130, a discharge unit 120 and a control unit 110. In structure, the discharge unit 120 is electrically connected to the DUT 190, and the control unit 110 is electrically connected to the measurement unit 130 and the discharge unit 120.

In practice, for example, the control unit 110 can include a field programmable gate array (FPGA) and its peripheral circuits (e.g., a switching circuit), and the discharge unit 120 can be the discharge device or the discharge circuit. The measurement unit 130 can be a measurement device or a measurement circuit, which can perform contact measurement or non-contact inductive measurement.

In some embodiments of the present disclosure, the measurement unit 130 is configured to measure the voltage value of the DUT 190. The control unit 110 flexibly adjusts the resistance value of the discharge unit 120 based on the voltage value of the DUT 190.

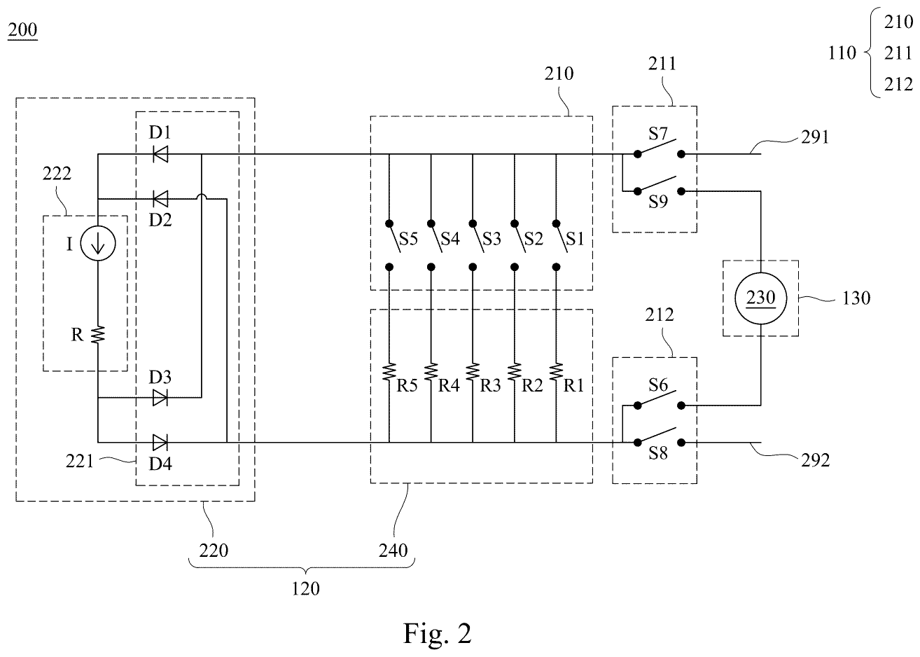

In order to further explain the measurement unit 130, the discharge unit 120 and the control unit 110, refer to FIG. 1 and FIG. 2. FIG. 2 is a circuit diagram of a discharge device 200 according to some embodiments of the present disclosure.

In some embodiments of the present disclosure, the discharge device 200 may include the floating active load 220 and the resistor network 240. In structure, the resistor network 240 is electrically connected to the floating active load 220. In practice, for example, two DUT connection ends 291 and 292 can be used to connect the DUT 190, and the discharge device 200 uses the floating active load 220 and the resistor network 240 to discharge at the same time, thereby improving the discharge speed of the capacitance of the DUT 190.

In practice, for example, the discharge device 200 can include the discharge unit 120. The discharge unit 120 can include the floating active load 220 and the resistor network 240.

Regarding the structure of the floating active load 220, in some embodiments of the present disclosure, the floating active load 220 includes a bridge rectifier circuit 221 and a active load 222. In structure, the bridge rectifier circuit 221 is electrically connected to the resistor network 240, and the active load 222 is electrically connected to the bridge rectifier circuit 221. In practice, for example, the bridge rectifier circuit 221 can solve the problem of the voltage polarity during the discharge, and therefore the discharge is not affected adversely by the voltage polarity.

Regarding the structure of the resistor network 240, in some embodiments of the present disclosure, the resistor network 240 includes a plurality of resistors R1-R5, the control unit 110 is electrically connected to the plurality of resistors R1-R5 through a plurality of switches S1-S5, and the control unit 110 controls the on/off state of the plurality of switches S1-S5 based on the voltage value of the DUT 190, thereby adjusting a parallel resistance value of the resistor network 240, thereby increasing the discharge voltage range and shortening the time period of the discharge.

Regarding the structure of the bridge rectifier circuit 221, in some embodiments of the present disclosure, the bridge rectifier circuit 221 includes a first diode D1, a second diode D2, a third diode D3 and a fourth diode D4. In structure, the cathode of the first diode D1 is electrically connected to an end of the active load 222, the cathode of the second diode D2 is electrically connected to the end of the active load 222, the anode of the second diode D2 is electrically connected to the resistor network 240, the cathode of the third diode D3 is electrically connected to the anode of the first diode D1, the anode of the third diode D3 is electrically connected to another end of the active load 222, the cathode of the fourth diode D4 is electrically connected to the anode of the second diode D2, and the anode of the fourth diode D4 is electrically connected to above-mentioned another end of the active load 222.

Regarding the structure of the active load 222, in some embodiments of the present disclosure, the active load 222 includes a current source I and a resistance element R. In structure, an end of the current source I is electrically connected to the cathode of the first diode D1 and the cathode of the second diode D2, an end of the resistance element R is electrically connected to another end of the current source I, and another end of the resistance element R is electrically connected to the anode of the third diode D3 and the anode of the fourth diode D4.

In some embodiments of the present disclosure, the discharge device 200 further includes a first switching circuit 210. In structure, an end of the first switching circuit 210 is electrically connected to an end of the floating active load 220, another end of the first switching circuit 210 is electrically connected to an end of the resistor network 240, and another end of the resistor network 240 is electrically connected to another end of the floating active load 222.

In some embodiments of the present disclosure, the resistor network 240 includes a plurality of resistors R1-R5, and the first switching circuit 210 includes a plurality of switches S1-S5. The plurality of switches S1-S5 are electrically connected to the plurality of resistors R1-R5 respectively, and the plurality of resistors R1-R5 are connected in parallel, and the on/off state of the plurality of switches S1-S5 of the first switching circuit 210 determines the parallel resistance value of the resistor network 240.

In some embodiments of the present disclosure, the discharge device 200 further includes a second switching circuit 211, a third switching circuit 212 and a voltage measurement circuit 230. In structure, the second switching circuit 211 is electrically connected to an end of the first switching circuit 210 and the DUT connection end 291, and the third switching circuit 212 is electrically connected to another end of the resistor network 240 and another DUT connection end 292. Two ends of the voltage measurement circuit 230 are electrically connected to the second switching circuit 211 and the third switching circuit 212 respectively, and the on/off state of a plurality of switches S1-S5 of the first switching circuit 210 is based on the voltage value between the DUT connection end 291 and the DUT connection end 292, in which the voltage value is measured by the voltage measurement circuit 230.

In practice, for example, when the voltage value (e.g., discharge voltage) of the DUT 190 is less than a first voltage (e.g., about 60V) and greater than or equal to a second voltage (e.g., about 35V), the control unit 110 is based on the voltage value of the DUT 190 to turn off the plurality of switches S1-S5 to be turned off. When the voltage value of the DUT 190 is less than the second voltage and greater than or equal to a third voltage (e.g., about 20V), the control unit 110 is based on the voltage value of the DUT 190 to turn off the plurality of switches S2-S5 and to turn on the switch S1. When the voltage value of the DUT 190 is less than the third voltage and greater than or equal to a fourth voltage (e.g., about 10V), and the control unit 110 is based on the voltage value of the DUT 190 to turn off the plurality of switches S3-S5 and to turn on the switches S1-S2, so that the resistors R1-R2 can be connected in parallel. When the voltage value of the DUT 190 is less than the fourth voltage and greater than or equal to a fifth voltage (e.g., about 2V), the control unit 110 is based on the voltage value of the DUT 190 to turn off a plurality of switches S4-S5 and to turn on the switches S1-S3, so that the resistors R1-R3 can be connected in parallel. When the voltage value of the DUT 190 is less than the fifth voltage and greater than or equal to a sixth voltage (e.g., about 0.8V), the control unit 110 is based on the voltage value of the DUT 190 to turn off the switch S5 and turns on the switches S1-S4, so that the resistors R1-R4 are connected in parallel. When the voltage value of the DUT 190 is less than the sixth voltage, the control unit 110 is based on the voltage value of the DUT 190 to turn on the switches S1-S5, so that the resistors R1-R5 are connected in parallel. The resistor network 240 solves the problem of being unable to discharge when the discharge voltage is less than 2V, and can also improve the discharge speed.

In practice, for example, the resistance value of the resistor R1 (e.g., about 240Ω) is greater than the resistance value of the resistor R2 (e.g., about 100Ω), the resistance value of the resistor R2 is greater than the resistance value of the resistor R3 (e.g., about 51Ω), the resistance value of the resistor R3 is greater than the resistance value of the resistor R4 (e.g., about 10Ω), and the resistance value of the resistor R4 is greater than the resistance value of the resistor R5 (e.g., about 3Ω).

As used herein, “around”, “about”, “substantially” or “approximately” shall generally mean within 20 percent, preferably within 10 percent, and more preferably within 5 percent of a given value or range. Numerical quantities given herein are approximate, meaning that the term “around”, “about”, “substantially” or “approximately” can be inferred if not expressly stated.

In practice, for example, the second switching circuit 211 includes switches S9 and S7. Two ends of the switch S9 are electrically connected to an end of the first switching circuit 210 and an end of the voltage measurement circuit 230. Two ends of the switch S7 are electrically connected to the end of the first switching circuit 210 and the DUT connection end 291.

In practice, for example, the third switching circuit 212 includes switches S6 and S8. Two ends of the switch S6 are electrically connected to above-mentioned another end of the resistor network 240 and another end of the voltage measurement circuit 230. Two ends of the switch S7 are electrically connected to above-mentioned another end of the resistor network 240 and the DUT connection end 292.

In practice, for example, the control unit 110 can electrically connects the DUT 190 by turning on the switches S7 and S8. Furthermore, the control unit 110 enables the voltage measurement circuit 230 to measure the voltage value of the discharge voltage of the DUT 190 by turning on the switches S9 and S6.

In view of the above, technical advantages are generally achieved, by embodiments of the present disclosure. With the discharge device 200 and the testing machine 100 of the present disclosure, there is no influence of the voltage polarity during the discharge, the discharge voltage range is increased, and the time period of the discharge is shortened.

It will be apparent to those skilled in the art that various modifications and variations can be made to the structure of the present invention without departing from the scope or spirit of the invention. In view of the foregoing, it is intended that the present invention cover modifications and variations of this invention provided they fall within the scope of the following claims.

What is claimed is:

1. A discharge device, comprising:
a floating active load; and
a resistor network electrically connected to the floating active load.

2. The discharge device of claim 1, wherein the floating active load comprises:
a bridge rectifier circuit electrically connected to the resistor network; and
an active load electrically connected to the bridge rectifier circuit.

3. The discharge device of claim 2, wherein the bridge rectifier circuit comprises:
a first diode, wherein a cathode of the first diode is electrically connected to an end of the active load;
a second diode, wherein a cathode of the second diode is electrically connected to the end of the active load, and an anode of the second diode is electrically connected to the resistor network;
a third diode, wherein a cathode of the third diode is electrically connected to an anode of the first diode, and an anode of the third diode is electrically connected to another end of the active load; and
a fourth diode, wherein a cathode of the fourth diode is electrically connected to the anode of the second diode, and an anode of the fourth diode is electrically connected to the another end of the active load.

4. The discharge device of claim 3, wherein the active load comprises:
a current source, wherein an end of the current source is electrically connected to the cathode of the first diode and the cathode of the second diode; and
a resistance element, wherein an end of the resistance element is electrically connected to another end of the current source, and another end of the resistance element is electrically connected to the anode of the third diode and the anode of the fourth diode.

5. The discharge device of claim 1, further comprising:
a first switching circuit, wherein an end of the first switching circuit is electrically connected to an end of the floating active load, another end of the first switching circuit is electrically connected to an end of the resistor network, and another end of the resistor network is electrically connected to another end of the floating active load.

6. The discharge device of claim 5, wherein the resistor network comprises a plurality of resistors, the first switching circuit comprises a plurality of switches, the plurality of switches are electrically connected to the plurality of resistors respectively, the plurality of resistors are connected in parallel with each other, and an on/off state of the plurality of switches of the first switching circuit determines a parallel resistance value of the resistor network.

7. The discharge device of claim 6, further comprising:
a second switching circuit electrically connected to the end of the first switching circuit and a DUT (device under test) connection end;
a third switching circuit electrically connected to the another end of the resistor network and another DUT connection end; and
a voltage measurement circuit, wherein two ends of the voltage measurement circuit are electrically connected to the second switching circuit and the third switching circuit respectively, and the on/off state of the plurality of the switches of the first switching circuit is based on an voltage value between the DUT connection end and the another DUT connection end, and the voltage value is measured by the voltage measurement circuit.

8. A testing machine, comprising:
a measurement unit configured to measure a voltage value of a DUT;
a discharge unit electrically connected to the DUT; and
a control unit electrically connected to the measurement unit and the discharge unit, the discharge unit comprising a floating active load and a resistor network, and the resistor network electrically connected to the floating active load.

9. The testing machine of claim 8, wherein the resistor network comprises a plurality of resistors, the control unit is electrically connected to the plurality of the resistors through a plurality of switches, and the control unit controls an on/off state of the plurality of the switches based on the voltage value of the DUT, thereby adjusting a parallel resistance value of the resistor network.

10. The testing machine of claim 8, wherein the floating active load comprises:
a bridge rectifier circuit electrically connected to the resistor network; and
an active load electrically connected to the bridge rectifier circuit.

11. The testing machine of claim 10, wherein the bridge rectifier circuit comprises:
a first diode, wherein a cathode of the first diode is electrically connected to an end of the active load;
a second diode, wherein a cathode of the second diode is electrically connected to the end of the active load, and an anode of the second diode is electrically connected to the resistor network;
a third diode, wherein a cathode of the third diode is electrically connected to an anode of the first diode, and an anode of the third diode is electrically connected to another end of the active load; and
a fourth diode, wherein a cathode of the fourth diode is electrically connected to the anode of the second diode, and an anode of the fourth diode is electrically connected to the another end of the active load.

12. The testing machine of claim 11, wherein the active load comprises:
a current source, wherein an end of the current source is electrically connected to the cathode of the first diode and the cathode of the second diode; and
a resistance element, wherein an end of the resistance element is electrically connected to another end of the current source, and another end of the resistance element is electrically connected to the anode of the third diode and the anode of the fourth diode.

13. The testing machine of claim 8, wherein the control unit comprises:
a first switching circuit, wherein an end of the first switching circuit is electrically connected to an end of the floating active load, another end of the first switching circuit is electrically connected to an end of the resistor network, and another end of the resistor network is electrically connected to another end of the floating active load.

14. The testing machine of claim 13, wherein the resistor network comprises a plurality of resistors, the first switching circuit comprises a plurality of switches, the plurality of switches are electrically connected to the plurality of resistors respectively, the plurality of resistors are connected in parallel with each other, and an on/off state of the plurality of switches of the first switching circuit determines a parallel resistance value of the resistor network.

15. The testing machine of claim 14, wherein the control unit further comprises: a second switching circuit electrically connected to the end of the first switching circuit and a DUT connection end; and a third switching circuit electrically connected to the another end of the resistor network and another DUT connection end,
wherein the measurement unit comprises a voltage measurement circuit, wherein two ends of the voltage measurement circuit are electrically connected to the second switching circuit and the third switching circuit respectively, and the on/off state of the plurality of the switches of the first switching circuit is based on the voltage value between the DUT connection end and the another DUT connection end, and the voltage value is measured by the voltage measurement circuit.
